(19) United States
(12) Patent Application Publication
(10) Pub. No.: US 2012/0274602 A1
(43) Pub. Date: Nov. 1, 2012

(54) WIRING AND PERIPHERY FOR INTEGRATED CAPACITIVE TOUCH DEVICES

(75) Inventors: Ion Bita, San Jose, CA (US); Rashmi Raghavendra Rao, Santa Clara, CA (US); Kebin Li, Fremont, CA (US)

(73) Assignee: QUALCOMM MEMS TECHNOLOGIES, INC., San Diego, CA (US)

(21) Appl. No.: 13/290,001

(22) Filed: Nov. 4, 2011

Related U.S. Application Data
(60) Provisional application No. 61/480,970, filed on Apr. 29, 2011.

(51) Int. Cl. G06F 3/044; H01K 3/10; H05K 1/11

(52) U.S. Cl. 345/174; 327/517; 29/852

(57) ABSTRACT

This disclosure provides systems, methods and apparatus for a projected capacitive touch (PCT) sensor that may include thin sensor electrodes coated with additional layers to form an optical cavity that reinforces a wavelength range or color of incident light. The sensor electrodes and a cover glass border and/or decorations may be fabricated simultaneously. In some implementations, the thickness of the optical cavity will be selected such that the “color” of reflected light is black. The sensor electrodes may not be noticeable to a human observer. However, in some other implementations, the thickness of the optical cavity may be selected such that the sensor electrodes and/or the decorative portions will have another color. Routing wires of the touch sensor may be shielded by a grounded conductive layer in the border.

### CROSS-REFERENCE TO RELATED APPLICATIONS

This application claims priority to U.S. Provisional Patent Application No. 61/480,970, entitled “WIRING AND PERIPHERY FOR INTEGRATED CAPACITIVE TOUCH DEVICES” (Attorney Docket No. QUALP050P/101798P1) and filed on Apr. 29, 2011, which is hereby incorporated by reference and for all purposes.

### TECHNICAL FIELD

This disclosure relates to display devices, including but not limited to display devices that incorporate touch screens.

### DESCRIPTION OF THE RELATED TECHNOLOGY

Electromechanical systems (EMS) include devices having electrical and mechanical elements, actuators, transducers, sensors, optical components (including mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). As used herein, the term interferometric modulator or interferometric light modulator refers to a device that selectively absorbs and/or reflects light using the principles of optical interference. In some implementations, an interferometric modulator may include

a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

The increased use of touch screens in handheld devices causes increased complexity and cost for modules that now include the display, the touch panel and a cover glass. As used herein, a “cover glass” may be formed of any suitable substantially transparent substrate, such as actual glass, polymer, etc. Each piece of glass adds thickness and requires costly glass-to-glass bonding solutions for attachment to the neighboring substrates. These problems can be further exacerbated for reflective displays when a frontlight also needs to be integrated, adding to the thickness and cost of the module.

### SUMMARY

The systems, methods and devices of the disclosure each have several innovative aspects, no single one of which is solely responsible for the desirable attributes disclosed herein.

One innovative aspect of the subject matter described in this disclosure can be implemented in an apparatus which includes a display cover glass having a projected capacitive touch (PCT) sensor. The projected capacitive touch sensor may include thin wires as the sensing electrodes. The thin sensor electrodes and/or the decorative portions may be coated with additional layers to form an optical cavity that reinforces a wavelength range or color of incident light. In some implementations, the thickness of the optical cavity will be selected such that the “color” of the reflected light is black. The sensor electrodes may not be noticeable to a human observer.

In some implementations, the sensor electrodes for the touch sensor and the cover glass border and/or decorations may be fabricated simultaneously, using the same layer or layers deposited on the cover glass. However, in some other implementations, the thickness of the optical cavity may be selected such that the sensor electrodes and/or the decorative portions will have a color other than black. In some implementations, the sensor electrodes will have one color and the border and/or the decorative portions will have another color. Graphical elements, such as company names, logos, icons, etc., may be incorporated into the border by patterning the black or colored border surrounding the viewable area of the display. In some implementations, routing wires of the touch sensor may be shielded by a grounded conductive layer in the border.

Another innovative aspect of the subject matter described in this disclosure can be implemented in a method that involves depositing optical cavity layers on a substantially transparent substrate to form a plurality of sensor electrodes. The method may involve depositing a substantially transparent dielectric material on the optical cavity layers and on exposed areas of the substantially transparent substrate, forming vias through the substantially transparent dielectric material to expose portions of the underlying optical cavity layers, and depositing conductive material in the vias to form electrical connections between the portions of the underlying optical cavity layers.

Depositing the optical cavity layers may involve depositing black mask layers. In some implementations, the black mask layers may provide a photopic integrated reflectivity of less than a threshold amount in the visible range of light. For example, the black mask layers may provide a photopic integrated reflectivity of less than 5%, less than 3%, less than 1% or less than some other threshold across a wavelength range from 350 nm to 800 nm.

Depositing the optical cavity layers may involve depositing a partially reflective and partially conductive layer, an oxide layer and/or a reflective and conductive layer. Depositing the oxide layer may involve depositing a silicon dioxide layer or an indium tin oxide layer. Depositing the partially reflective and partially conductive layer may involve depositing a molybdenum-chromium (MoCr) alloy layer.

The sensor electrodes may be formed in a sensing area. Depositing the optical cavity layers may involve forming a border area that extends around at least part of the sensing area. Depositing the oxide layer may involve forming the optical cavity layers to reinforce a first color in the border area and forming the optical cavity layers of the sensor electrodes to reinforce a second color. Depositing the conductive material may involve forming routing wires in the border area. The routing wires may be configured for connecting the sensor electrodes with control circuitry.

The method also may involve forming an electrical connection between a grounding wire and a conductive layer of the optical cavity layers in the border area. Forming the vias may involve forming at least one via in the border area configured to expose a conductive layer of the optical cavity layers. The method also may involve connecting the conductive layer to an electrically grounded wire through the via in the border area. The method also may involve forming a via through at least one of the optical cavity layers in the border area to create a decoration. In some implementations, the decoration may be a logo.

Depositing the optical cavity layers may involve forming an optical cavity that will reinforce a wavelength range or color of incident light. Depositing the optical cavity layers may involve forming projected capacitive touch sensor electrodes. Depositing the optical cavity layers may involve forming first projected capacitive touch sensor electrodes in continuous columns and second projected capacitive touch sensor electrodes in discontinuous rows. Depositing the conductive material may involve forming electrical connections between the discontinuous rows. Depositing the optical cavity layers may involve forming first projected capacitive touch sensor electrodes in discontinuous columns and second projected capacitive touch sensor electrodes in continuous rows. Depositing the conductive material may involve forming electrical connections between the discontinuous columns.

Another innovative aspect of the subject matter described in this disclosure can be implemented in an apparatus that includes a substantially transparent substrate and a plurality of touch sensor electrodes disposed on the substantially transparent substrate. The touch sensor electrodes may include optical cavity layers. Substantially transparent dielectric material may be disposed on the optical cavity layers and vias may be formed through the substantially transparent dielectric material to portions of the optical cavity layers. Conductive material in the vias may form electrical connections between the portions of the optical cavity layers.

The optical cavity layers may include black mask layers. The black mask layers may provide a photopic integrated reflectivity of less than a threshold (e.g., 1%, 3% or 5%) across a wavelength range from 350 nm to 800 nm. The optical cavity layers may include a partially reflective and partially conductive layer, an oxide layer and/or a reflective and conductive layer. The partially reflective and partially conductive layer may be a molybdenum-chromium (MoCr) alloy layer. The oxide layer may be, for example, a silicon dioxide layer or an indium tin oxide layer. The optical cavity layers may form an optical cavity configured to reinforce a wavelength range or color of incident light.

The apparatus may include a border area around the touch sensor electrodes. The border area may be formed of the optical cavity layers. First optical cavity layers that form the border area may be configured to reinforce a first color and second optical cavity layers that form the touch sensor electrodes may be configured to reinforce a second color.

The touch sensor electrodes may include first touch sensor electrodes in continuous columns and second touch sensor electrodes in discontinuous rows. The conductive material may form electrical connections between the discontinuous rows. The touch sensor electrodes may include first touch sensor electrodes in discontinuous columns and second touch sensor electrodes in continuous rows. The conductive material may form electrical connections between the discontinuous columns.

The apparatus may include a display and a processor that is configured to communicate with the display. The processor may be configured to process image data. The apparatus also may include a memory device that is configured to communicate with the processor. The apparatus may include a driver circuit configured to send at least one signal to the display and a controller configured to send at least a portion of the image data to the driver circuit. The apparatus may include an image source module configured to send the image data to the processor, wherein the image source module includes at least one of a receiver, transceiver, and transmitter. The apparatus may include an input device configured to receive input data and to communicate the input data to the processor. The apparatus may include a touch controller configured for communication with the processor and routing wires configured for connecting the sensor electrodes with the touch controller.

Details of one or more implementations of the subject matter described in this specification are set forth in the accompanying drawings and the description below. Although the examples provided in this summary are primarily described in terms of MEMS-based displays, the concepts provided herein may apply to other types of displays, such as liquid crystal displays, organic light-emitting diode (“OLED”) displays and field emission displays. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9A shows an example of a cross-section through a portion of a device having projected capacitive touch sensor electrodes formed of optical cavity layers.

FIG. 9B shows an example of a graph of the spectral response of optical cavity layers configured to produce a black appearance.

FIG. 9C shows an example of a graph of color coordinates of optical cavity layers configured to reinforce a red color and a green color.

FIG. 10 shows an example of a flow diagram illustrating a process of fabricating a device having projected capacitive touch sensor electrodes formed of optical cavity layers on a cover glass.

FIGS. 11A through 11C show examples of cross-sections through a portion of a cover glass during stages in the process of FIG. 10.

FIG. 12A shows an example of a spatial distribution of the sensor electrodes shown in FIG. 11C.

FIG. 12B shows an example of a bottom view of a cover glass having first projected capacitive touch sensor electrodes in discontinuous columns and second projected capacitive touch sensor electrodes in continuous rows formed thereon.

FIG. 12C shows an example of a cross-section through the cover glass and electrodes shown in FIG. 12B.

FIG. 12D shows an example of a bottom view of a portion of a cover glass according to an alternative implementation.

FIG. 12E shows an example of a cross-section through the cover glass, bond pads and via shown in FIG. 12D.

FIG. 12F shows an example of a cover glass having first projected capacitive touch sensor electrodes in discontinuous rows and second projected capacitive touch sensor electrodes in continuous columns formed thereon.

FIG. 12G shows an alternative example of a cover glass having first projected capacitive touch sensor electrodes in discontinuous rows and second projected capacitive touch sensor electrodes in continuous columns formed thereon.

FIG. 12H shows an example of a top view of a device having projected capacitive touch sensor electrodes and a border area formed of optical cavity layers on a cover glass.

FIG. 13A shows an alternative example of a top view of a device having a border area formed of optical cavity layers on a cover glass, with a logo formed in the border area.

FIG. 13B shows an example of a cross-section through the cover glass, border and logo shown in FIG. 13A.

FIG. 13C shows an alternative example of a cross-section through the cover glass, border and logo shown in FIG. 13A.

FIGS. 14A and 14B show examples of system block diagrams illustrating a display device that includes a touch sensor as described herein.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

According to some implementations provided herein, the metal sensor electrodes of a capacitive touch sensor may be coated with additional layers to form an optical cavity that reinforces a wavelength range or color of incident light. In some implementations, the thickness of the optical cavity will be selected such that the “color” is black. In some implementations, the sensor electrodes and a cover glass border surrounding the viewable area of a display may be fabricated simultaneously, using the same layer or layers deposited on a cover glass.

However, in some other implementations, the thickness of the optical cavity may be selected such that the thin metal wires and/or the decorative portions will have another color. Graphical elements, such as company names, logos, icons, etc., may be incorporated into the border by patterning the black or colored border.

Particular implementations of the subject matter described in this disclosure can be implemented to realize one or more of the following potential advantages. Such implementations can be advantageous because the wires of a capacitive touch sensor may be relatively less noticeable to a human observer. Moreover, the number of steps required for fabricating the capacitive touch sensor, the border, other decorative features, logos, etc., may be reduced. In some implementations, the sensor electrodes and a cover glass border and/or decorations, such as a logo, may be fabricated simultaneously. For example, vias may be etched through the optical cavity layers to the cover glass in the shape of a desired logo. The vias may be filled with ink, paint, metal, reflective tape, etc. Alternatively, the vias may be etched part of the way through the optical cavity layers, to expose a reflective layer in the shape of the logo. Grounding to the border may decrease cross-talk between the routing wires. Such implementations also may reduce or eliminate interference from ambient noise with the signals in the routing wires.

An example of a suitable electromechanical systems (EMS) or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

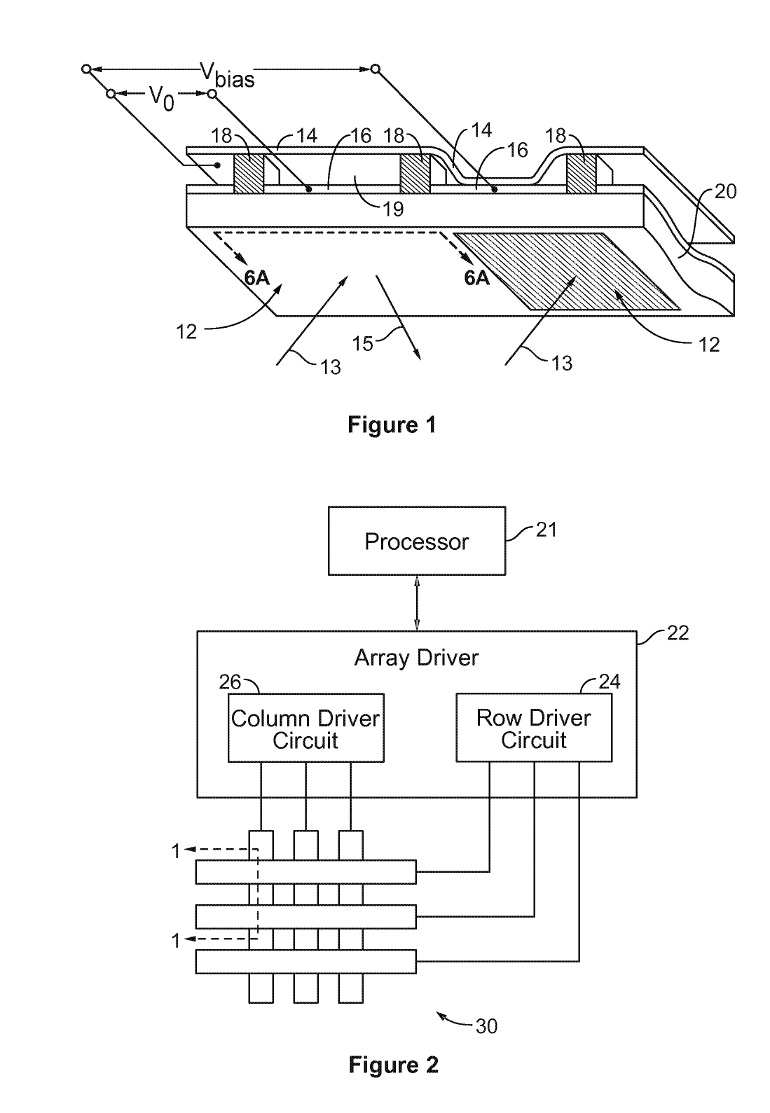

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than about 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the IMOD 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated IMOD 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

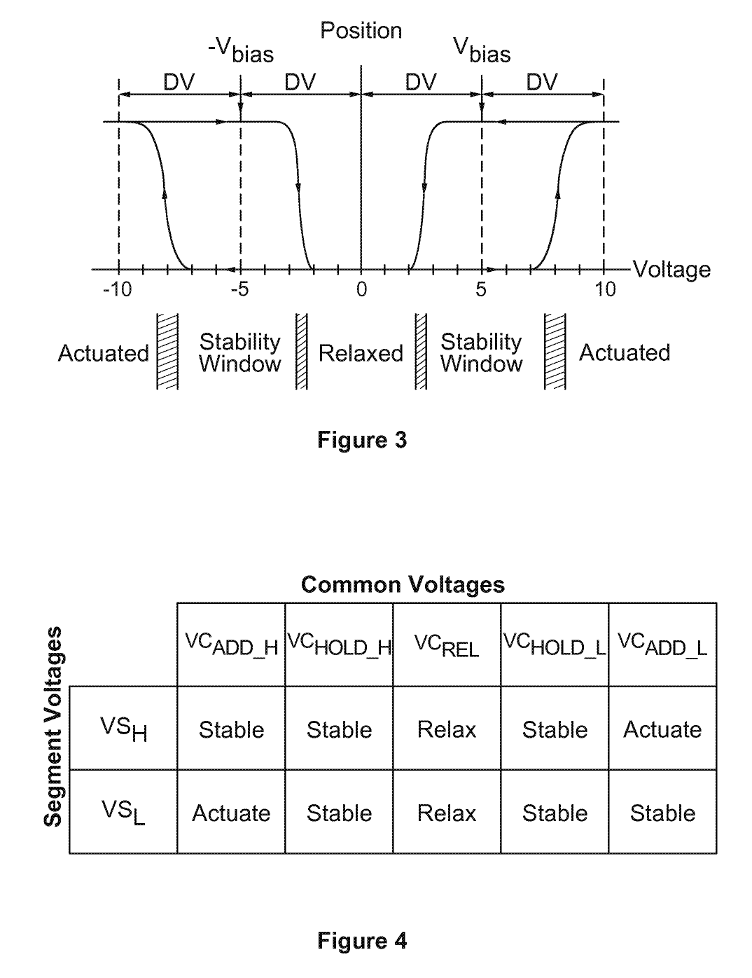

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10 volts. However, the movable reflective layer does not relax completely until the voltage drops below 2 volts. Thus, a range of voltage, approximately 3 to 7 volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10 volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7 volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

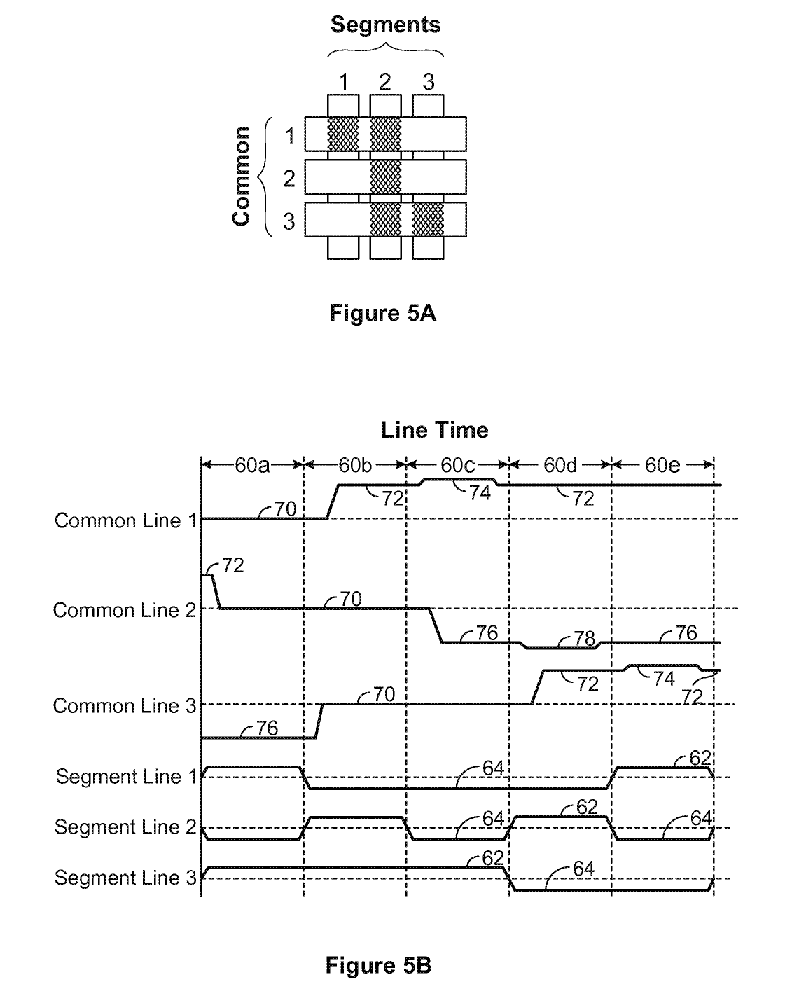

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a, a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}-relax and VC_{HOLD}_{_{—}}_{L}-stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

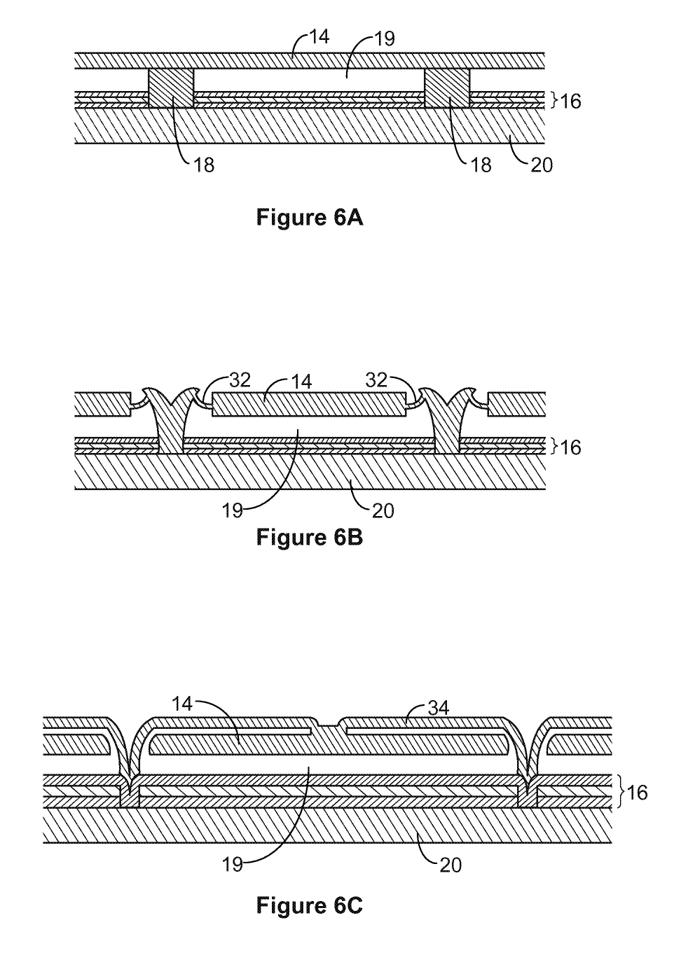

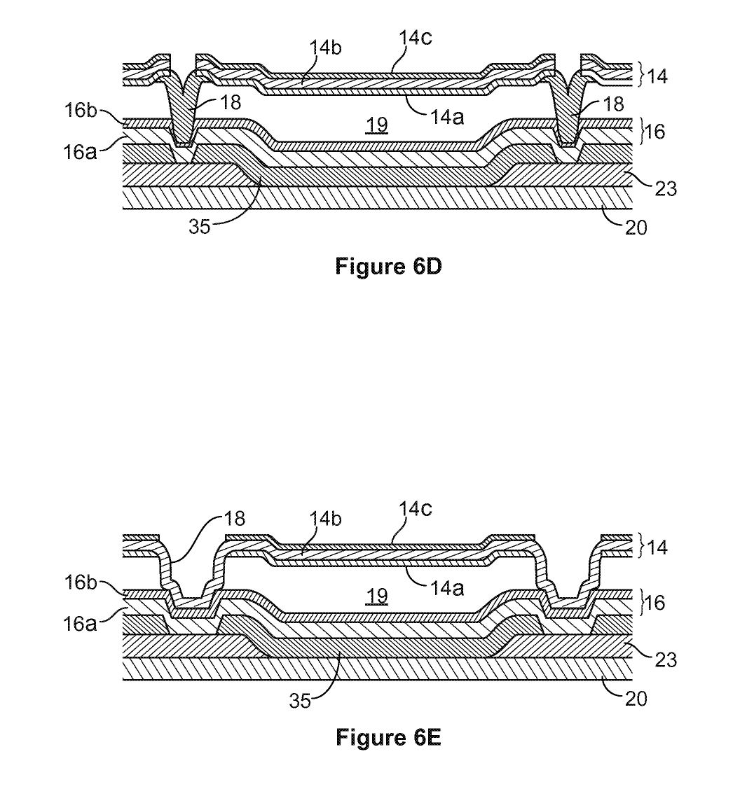

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self-supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as patterning.

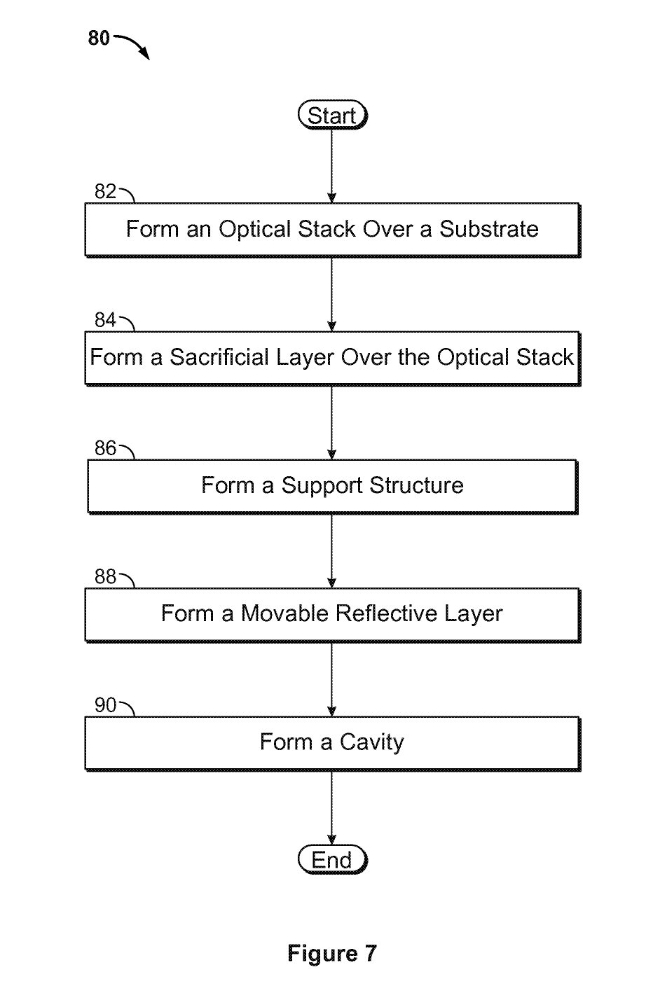

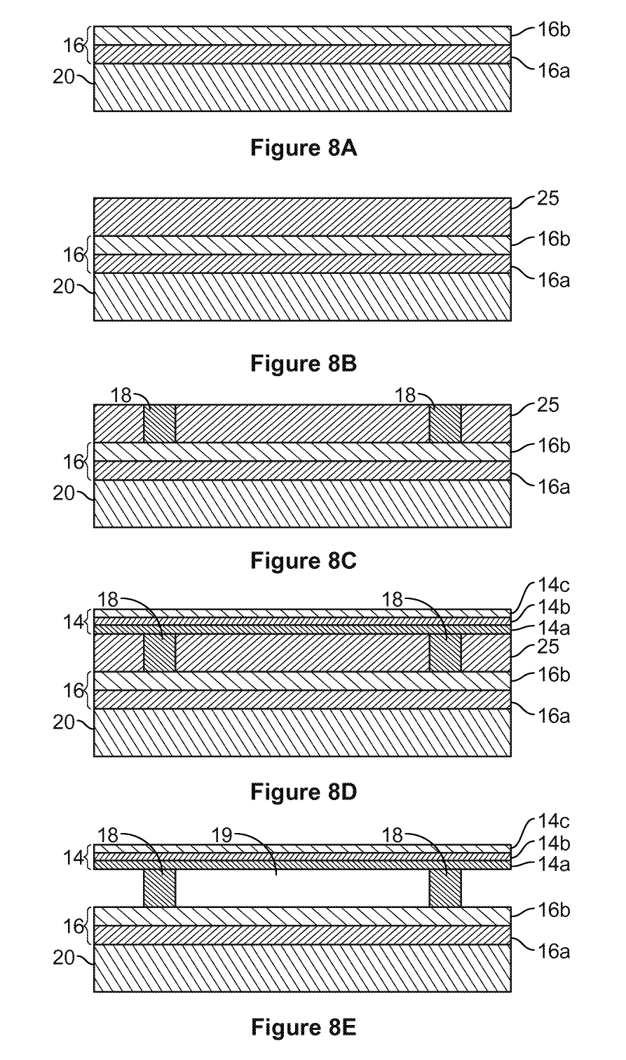

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition processes, e.g., reflective layer (e.g., aluminum, aluminum alloy) deposition, along with one or more patterning, masking, and/or etching processes. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other combinations of etchable sacrificial material and etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

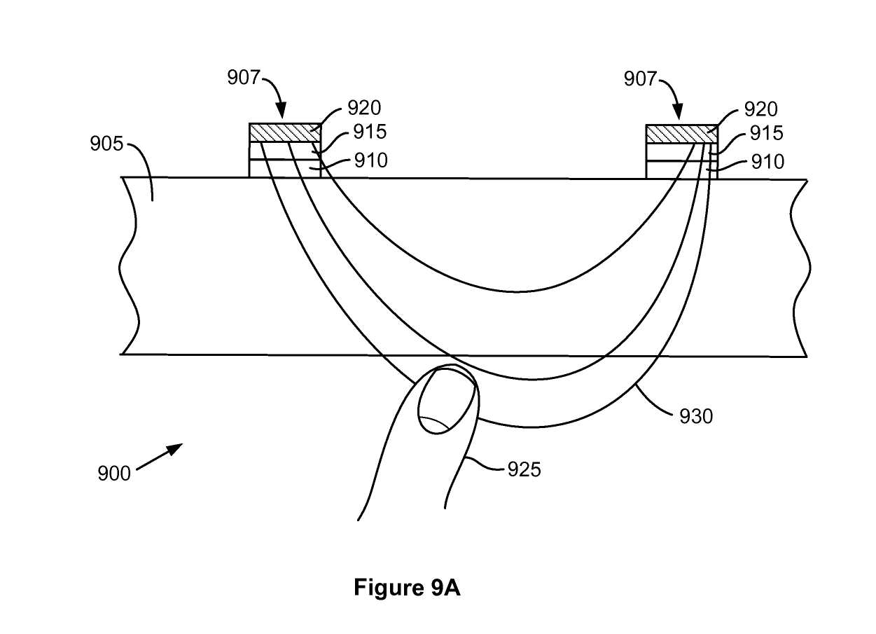

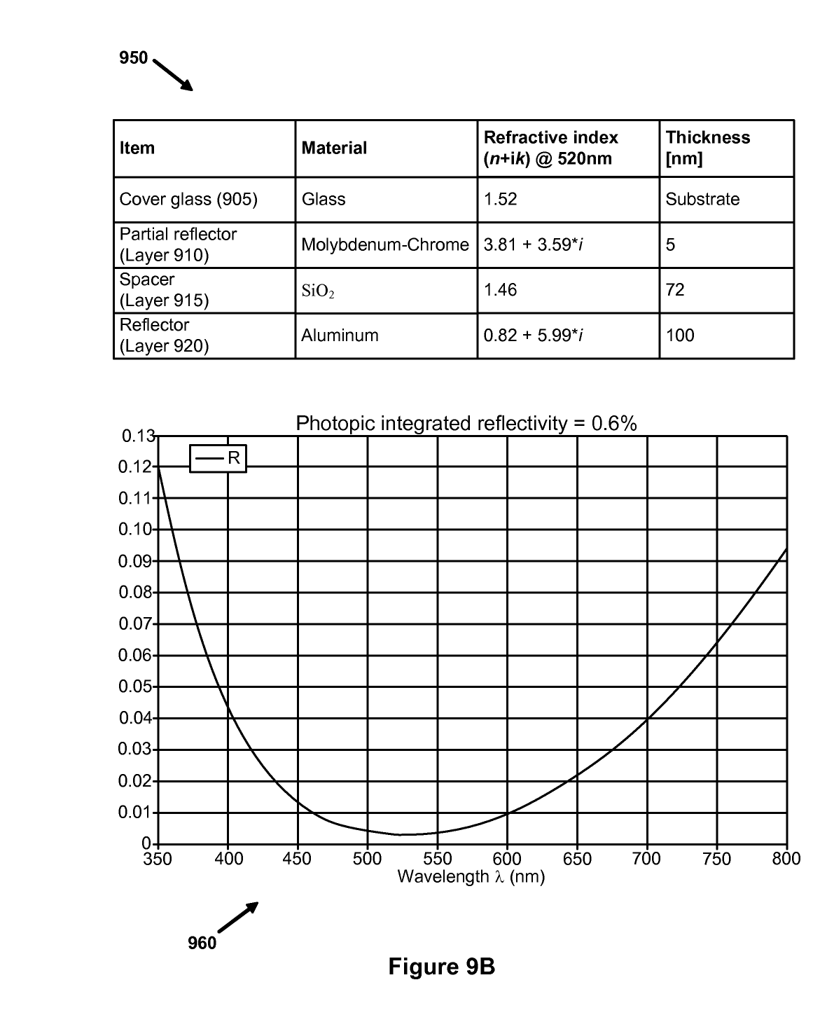

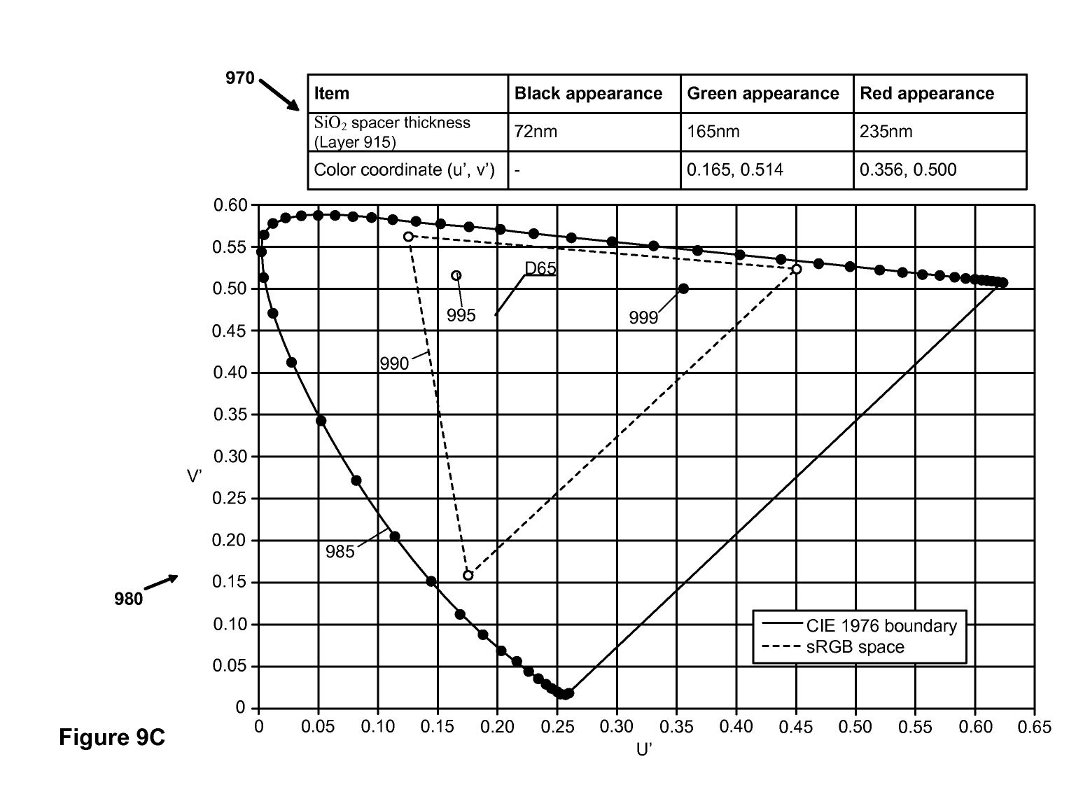

FIG. 9A shows an example of a cross-section through a portion of a device having projected capacitive touch sensor electrodes formed of optical cavity layers. The touch sensor device 900 includes sensor electrodes 907 disposed upon a cover glass 905. As noted elsewhere herein, the “cover glass” 905 may be formed of any suitable substantially transparent substrate, such as a type of actual glass, one or more layers of a polymer, combinations thereof, etc. The cover glass 905 may have coatings for desired functionality, such as an anti-reflection coating, an anti-glare coating, an anti-fingerprint coating, etc. In some such implementations, the sensor electrodes 907 may be formed on one side of the cover glass 905 and one or more such coatings may be formed on an opposing side of the cover glass 905.

In this implementation, the sensor electrodes 907 have been formed by depositing optical cavity layers on the cover glass 905. The optical cavity layers include layers 910, 915 and 920. Here, the layer 910 is formed of a partially reflective and partially transmissive material. The layer 910 also may be a conductive material. In some examples, the layer 910 may be formed of molychrome. In alternative examples, the layer 910 may be formed of other materials, such as Mo, Cr, etc.

In this implementation, the layer 915 is a substantially transparent oxide layer. The layer 915 may be formed of a substantially transparent dielectric material, such as SiO₂. Alternatively, the layer 915 may be formed of a substantially transparent conductive material, such indium tin oxide (ITO). In some such implementations, all of the optical cavity layers 910, 915 and 920 can be electrically conductive. Accordingly, electrical connections may be made with any or all of all of the optical cavity layers 910, 915 or 920.

The layer 920 is formed of a reflective material in this example. In some implementations, the layer 920 may be formed of a reflective and conductive material, such as Mo, Cr, Ni, Al, alloys thereof, etc. In this example, the layer 920 is an AlSi layer, which is thick enough to be almost completely reflective.

The thickness of the layer 915 may form an optical cavity that reinforces a wavelength range or color of incident light. In this example, the thickness of the optical cavity may be such that the “color” is black. In such implementations, the optical cavity layers may be configured to have optical properties similar to those of black mask layers. Such implementations can be desirable, because the sensor electrodes 907 may be less noticeable to an observer if they are black.

FIG. 9B shows an example of a graph of the spectral response of optical cavity layers configured to produce a black appearance. As noted elsewhere herein, such optical cavity layers may be referred to herein as a black mask, such as the black mask 23. FIG. 9B also shows examples of materials that may be used for such optical cavity layers, their refractive indices (n+ik) at 520 nm and their thicknesses. In this example, the table 950 includes a cover glass formed of glass having a refractive index of 1.52. The layer 910 is formed of MoCr having a refractive index of 3.81+3.59i and a thickness of 5 nm. The layer 915 is formed of SiO₂ having a refractive index of 1.46 and a thickness of 72 nm. The layer 920 is formed of Al having a refractive index of 0.82+5.99i and a thickness of 100 nm.

However, these materials, layer thicknesses, etc. are only examples. In other implementations, for example, the cover glass may be formed of a substantially transparent polymer, such as polycarbonate. In alternative implementations, the optical cavity layers also may be formed of different materials, with different thicknesses, etc. In some such implementations, the layer 910 may be formed of Mo, Cr, Si, any combination thereof, or some other suitable material. The layer 915 may be formed of another substantially transparent material, such as indium tin oxide (ITO), aluminum oxide, silicon nitride, silicon oxynitride, any combination thereof, or some other suitable material. The layer 920 may be formed of another reflective and conductive material, e.g., a conductive metal such as silver.

The reflectivity of this optical cavity is shown in the graph 960. Here, the reflectivity is shown over a wavelength range from 350 nm to 800 nm. The photopic integrated reflectivity across this wavelength range is approximately 0.6%. Accordingly, the optical cavity has a very low reflectivity, producing a black appearance. In alternative implementations, the black mask may be configured to produce a photopic integrated reflectivity across this wavelength range of less than 5%, less than 3%, less than 1% or less than some other threshold.

However, in some other implementations, the thickness of the layer 915 may be selected such that the sensor electrodes 907 will reinforce another color, such as blue, green, etc. As described in more detail below, in some implementations, a border around the cover glass 905 also may be formed from the optical cavity layers 910, 915 and 920. In some such implementations, the sensor electrodes 907 and the decorative portions will have the same color. However, in some other implementations, the sensor electrodes 907 and the decorative portions may have different colors.

FIG. 9C shows an example of a graph of color coordinates of optical cavity layers configured to reinforce a red color and a green color. FIG. 9C also includes the table 970, which indicates thicknesses of layer 915 for producing optical cavity layers configured to produce a black, green or red appearance. In this example, a thickness of 165 nm is noted to produce a green appearance and a thickness of 235 nm is noted to produce a red appearance.

Color coordinates for the red and green examples are indicated in the table 970 and shown in the graph 980. The graph 980 is based on a color space adopted by the International Commission on Illumination (CIE) in 1976, known as the CIE 1976 (L, u′, v′) color space, also known as the CIELUV color space. The curve 985 indicates the boundary for the CIELUV chromaticity diagram. The triangle 990 indicates the boundary of the sRGB color space, which is a widely-used RGB color space designed to be applicable to typical home and office viewing conditions. In this example, an optical cavity in which the layer 915 has a thickness of 165 nm has color coordinates of 0.165, 0.514, which correspond to location 995 within the green region of the sRGB color space. An optical cavity in which the layer 915 has a thickness of 235 nm has color coordinates of 0.356, 0.500, which correspond to location 999 within the red region of the sRGB color space. Other thicknesses of the layer 915 may be used to form optical cavities that reinforce these, or other colors.

If the sensor electrodes 907 are formed of an optical cavity that reinforces an actual color, the sensor electrodes 907 may be relatively more noticeable to an observer than the sensor electrodes 907 of the same width that have a black appearance. However, some colors may be less noticeable to a human observer than others. For example, a blue IMOD subpixel may reflect only a fraction of the visible spectrum, e.g., on the order of 20%. Accordingly, the sensor electrodes 907 that reinforce a blue color may not be visible. Moreover, the sensor electrodes 907 that reinforce a color may be made sufficiently narrow to that they will not be noticeable to an observer, or will be noticeable only in certain lighting conditions. In some implementations, for example, the sensor electrodes 907 may be on the order of microns in width, e.g., in the range of 1 to 10 microns wide.

The spacing between the sensor electrodes 907, however, may be orders of magnitude greater than their width. In some implementations, for example, the sensor electrodes 907 may be formed into polygons having sides that are in the range of 1 to 10 millimeters in length. In some implementations, the sensor electrodes 907 may be formed into sensor cells or “sensels” that have a size that is scaled according to the width of a typical finger 925. Some such examples are described below.

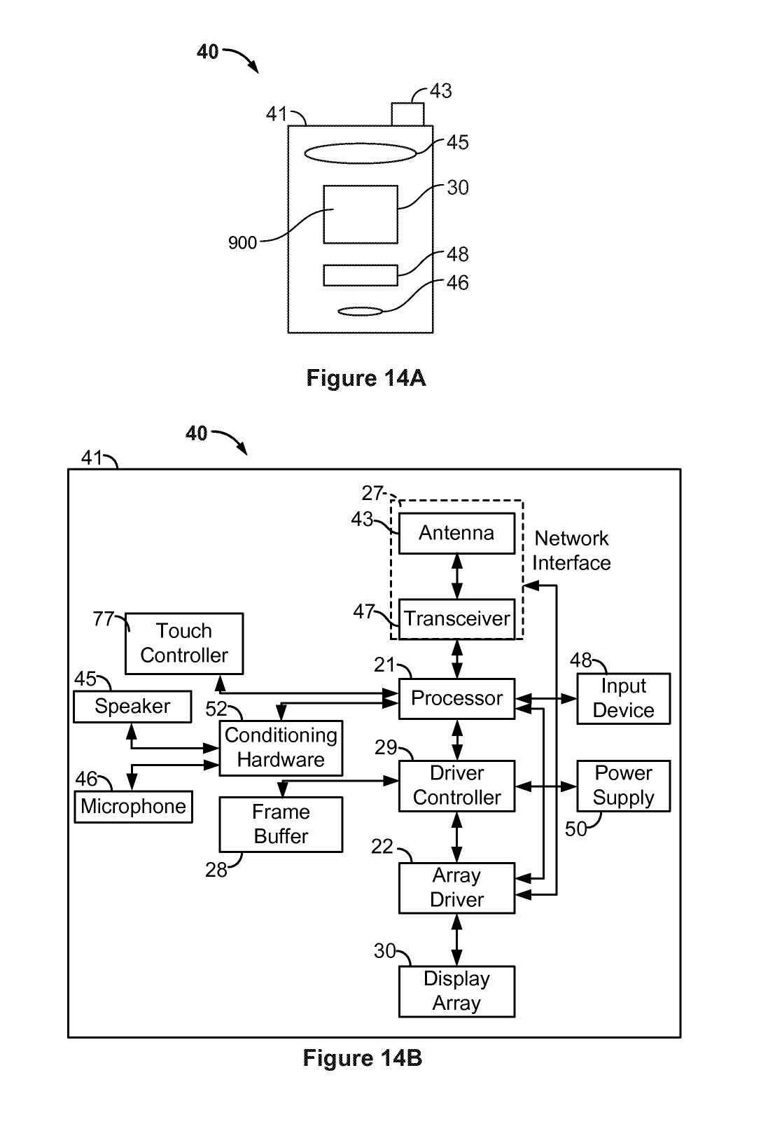

In FIG. 9A, the touch sensor device 900 is a projected capacitive touch sensor device. Bringing the finger 925, a conductive stylus, etc., close to the surface of the cover glass 905 changes the local electric field 930. The touch sensor device 900 is configured to detect changes in capacitance caused by proximity of the finger 925 to the cover glass 905. By detecting such changes in capacitance between the sensor electrodes 907, the touch sensor device 900 can determine a location of the finger 925. Such a determination may be made by a device such as touch controller 77, which is described below with reference to FIG. 14B. Alternatively, such a determination may be made (at least in part) by another device, such as a controller of a device to which the touch sensor device 900 is attached, e.g., processor 21 of FIG. 14B.

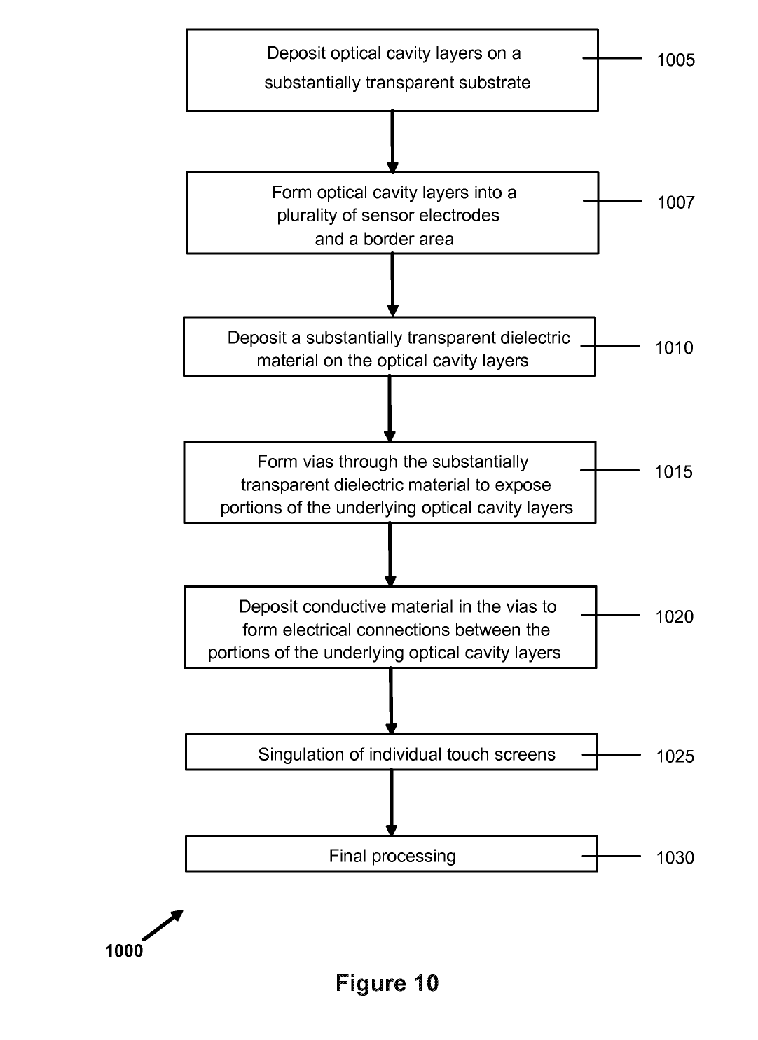

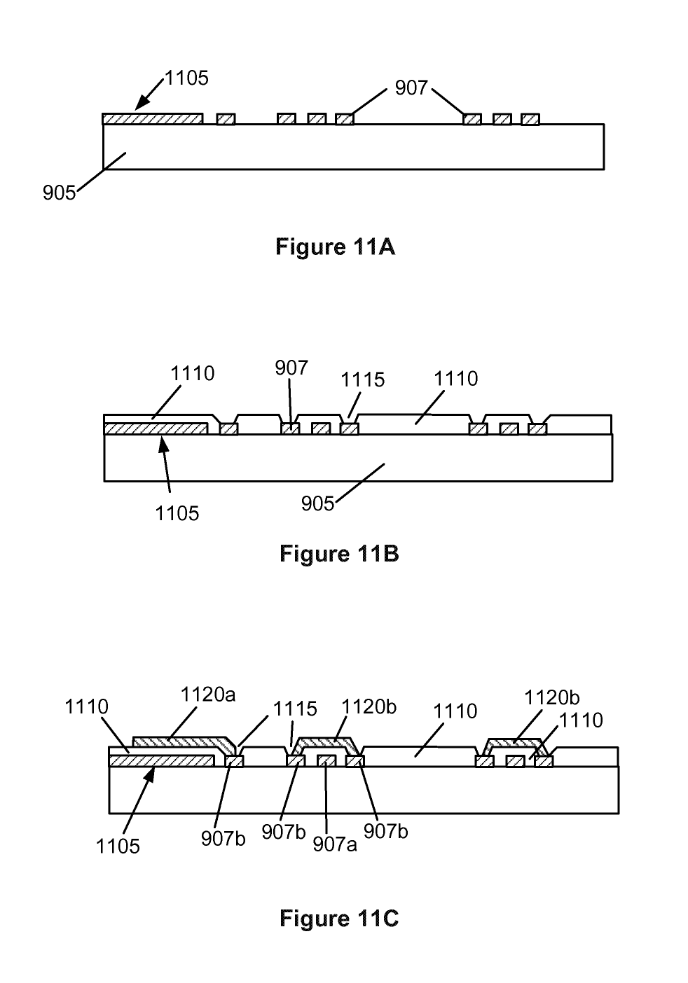

FIG. 10 shows an example of a flow diagram illustrating a process of fabricating a device having projected capacitive touch sensor electrodes formed of optical cavity layers on a cover glass. FIGS. 11A through 11C show examples of cross-sections through a portion of a cover glass during stages in the process of FIG. 10. As with other processes described herein, the blocks of process 1000 are not necessarily performed in the order indicated. Related processes may include more or fewer blocks than are shown in FIG. 10.

Process 1000 of FIG. 10 begins with block 1005, in which optical cavity layers are deposited on a substantially transparent substrate. The optical cavity layers may, for example, be similar to the layers 910, 915 and 920 discussed above with reference to FIG. 9A. The substantially transparent substrate may be similar to the cover glass 905 of FIG. 9A.

In block 1007, the optical cavity layers are patterned and etched into a plurality of sensor electrodes and a border area. In the example shown in FIG. 11A, optical cavity layers that have been deposited on cover glass 905 have been patterned and etched into the sensor electrodes 907 and the border area 1105. The optical cavity layers that form the sensor electrodes 907 may be deposited, patterned and etched at the same time that the border area 1105 is deposited, patterned and etched. For clarity, the individual optical cavity layers are not shown in FIGS. 11A through 11C.

In block 1010, a substantially transparent dielectric material is deposited on the optical cavity layers and on exposed portions of the substantially transparent substrate. Vias may be formed through the substantially transparent dielectric material in block 1015. For example, vias may be formed to expose portions of the underlying optical cavity layers. A variety of dielectric deposition processes followed by respective etch processes may be used, such as plasma-enhanced chemical vapor deposition of SiO₂ followed by dry or wet etching to open the vias. Alternatively, photoimageable materials such as an epoxy-based negative photoresist, a polyimide, etc., may be used. For example, one of the SU-8 family of compounds commercially available from MicroChem Corp. may be used. Alternatively, one of the GM1040, GM1060, GM1070 or GLM2060 compounds commercially available from Gersteltec SARL may be used.

One such example is shown in FIG. 11B. Here, the substantially transparent dielectric material 1110 has been deposited on the cover glass 905, on the sensor electrodes 907 and on the border area 1105. The vias 1115 have subsequently been formed to expose portions of the underlying optical cavity layers, such as the sensor electrodes 907.

In this implementation, conductive material is deposited, patterned and etched in block 1020. This conductive material may, for example, be deposited in the vias 1115 to form electrical connections between the underlying portions of the optical cavity layers. As shown in FIG. 11C, the conductive material 1120 may be patterned to form the routing wires 1120a and the jumpers 1120b that electrically connect the sensor electrodes 907 to one another. The routing wires 1120a and the jumpers 1120b may be fabricated from a variety of electrically conductive materials, such as a black mask stack or other optical cavity stack, a single conductive metal layer, ITO, etc.

In this example, the substantially transparent dielectric material 1110 can allow nearby sensor electrodes 907 to be electrically connected to one another while insulating these sensor electrodes 907 from being electrically connected to adjacent sensor electrodes 907. Here, for example, the jumpers 1120b electrically connect nearby portions of the sensor electrodes 907b by spanning portions of the sensor electrodes 907a. The substantially transparent dielectric material 1110 electrically insulates the overlying jumpers 1120b from the sensor electrodes 907a.

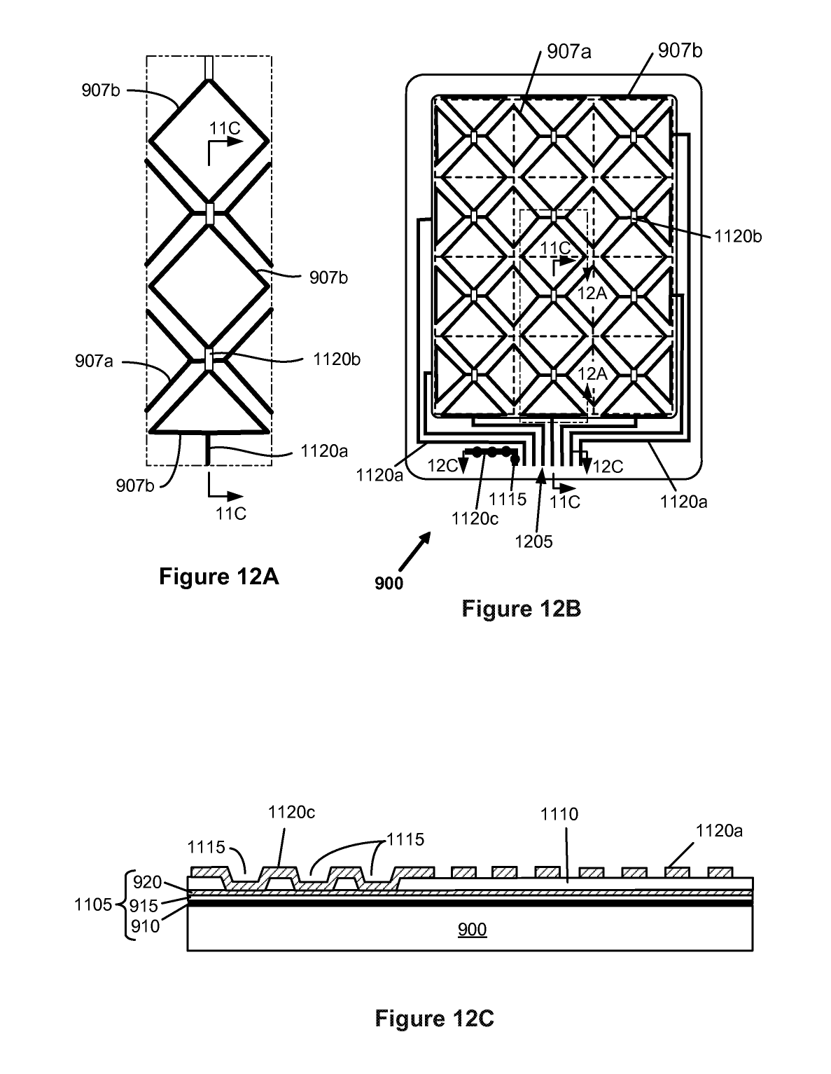

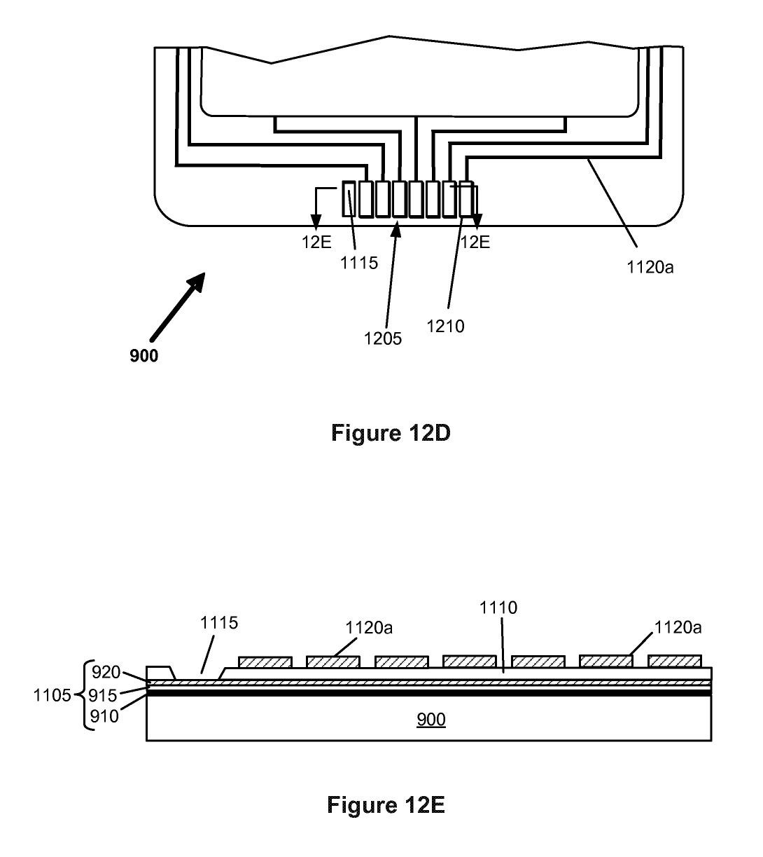

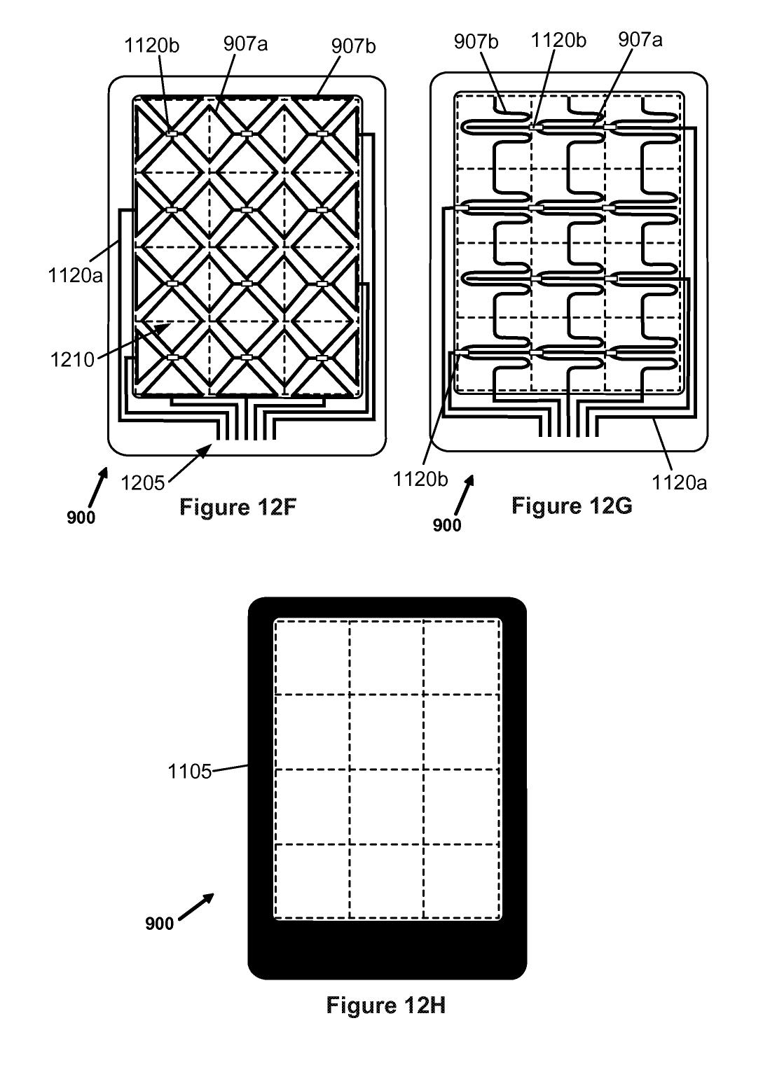

FIG. 12A shows an example of a spatial distribution of the sensor electrodes shown in FIG. 11C. FIG. 12A includes a dashed line that indicates a plane in which the cross-section of FIG. 11C is disposed. In this example, the sensor electrodes 907a and 907b have been formed into diamond shapes. The sensor electrodes 907a are formed into continuous rows, whereas the sensor electrodes 907b are formed into discontinuous columns. The jumpers 1120b electrically connect adjacent sensels of the sensor electrodes 907b by spanning portions of the continuous rows of the sensor electrodes 907a. One of the routing wires 1120a may be seen in a lower portion of FIG. 12A.

FIG. 12B shows an example of a bottom view of a cover glass having first projected capacitive touch sensor electrodes in discontinuous columns and second projected capacitive touch sensor electrodes in continuous rows formed thereon. FIG. 12B provides a simple example of a touch sensor device 900 that includes the sensor electrodes 907a and 907b shown in FIG. 12A. The dashed outline within the middle column of the touch sensor device 900 indicates the outline of FIG. 12A.

The number of sensels indicated in FIG. 12B is merely an example. Alternative touch sensor devices 900 may have more or fewer sensels. Some touch sensor devices 900 may have orders of magnitude more sensels. In some such examples, the sensels may be the order of a fingertip size, e.g., a few millimeters across. For example, one such touch sensor device 900 may include sensor electrodes 907a and 907b formed into rhombus-shaped sensels having sides that are between 1 and 10 millimeters in length. The sensor electrodes 907a and 907b may be between 1 and 10 microns wide, e.g., 5 microns wide.

The routing wires 1120a may be seen around the periphery of the touch sensor device 900. In this example, the routing wires 1120a are formed along with the sensor electrodes 907a and 907b, in block 1020 of FIG. 10. The routing wires 1120a may be connected with control circuitry, e.g., in the pad area 1205.

Referring again to FIG. 11C, a person having ordinary skill in the art may observe that the routing wires 1120a are separated from the conductive border area 1105 by the substantially transparent dielectric material 1110. The dielectric material 1110 may, in some implementations, be only a few microns in thickness. In some such implementations, there may be a risk of unwanted coupling between the routing wires 1120a and the conductive border area 1105.

In order to mitigate or eliminate this unwanted coupling, the routing wires 1120a may be shielded by an electrically grounded border area 1105 by making one or more additional vias 1115 through the dielectric material 1110 to the border area 1105. In some such implementations, a grounding wire may be formed in the vias 1115. Such a grounding wire may be configured to electrically connect a conductive portion of the border area 1105 to an external ground source. For example, block 1015 of FIG. 10 may involve forming additional vias, e.g., in the pad area 1205, for connecting such grounding wires. Such additional vias may be formed through the dielectric material 1110 to a conductive portion of the border area 1105. Such implementations may be advantageous because the cross-talk between the routing wires 1120a can be minimized. Such implementations also may reduce or eliminate interference from ambient with the signals in the routing wires 1120a.

Examples of such vias and grounding wires are shown in FIGS. 12B and 12C. Referring first to FIG. 12B, a grounding wire 1120c is shown in the pad area 1205. In this example, the grounding wire 1120c is positioned adjacent to the routing wires 1120a and is configured to be connected with a corresponding grounding wire of, e.g., a flex cable.

FIG. 12C shows an example of a cross-section through the cover glass and electrodes shown in FIG. 12B. The cross-section shown in FIG. 12C is made in the pad area 1205 through the grounding wire 1120c, three of the vias 1115 and seven of the routing wires 1120a. As shown in FIG. 12C, the vias 1115 connect the grounding wire 1120c to a conductive portion of the border area 1105. In this example, the grounding wire 1120c is grounded through multiple vias 1115, whereas in some other implementations the grounding wire 1120c may be grounded through only one of the vias 1115. The grounding wire 1120c extends into the vias 1115 and makes contact with the layer 920, which is formed of a conductive material in this example. Accordingly, the grounding wire 1120c is grounded to the layer 920 through the vias 1115

12D shows an example of a bottom view of a portion of a cover glass according to an alternative implementation. In this example, the routing wires 1120a terminate in bond pads 1210. This implementation does not include a grounding wire 1120c, but instead includes a single via 1115 adjacent the bond pads 1210.

FIG. 12E shows an example of a cross-section through the cover glass, bond pads and via shown in FIG. 12D. In this example, the bond pads 1210 have been formed on the dielectric material 1110 as part of the process of forming the routing wires 1120a (see FIG. 12D) and the sensor electrodes 907a and 907b (not shown). The via 1115 extends through the dielectric material 1110 to expose the layer 920, which is formed of conductive material in this example. The via 1115 may, for example, be configured to receive a protruding conductive portion of a flex cable's grounding wire (not shown).

Returning now to FIG. 10, in block 1025 individual touch screens are singulated. The blocks 1005 through 1020 may involve forming a large number of touch screens on a single substrate. After block 1025, an individual touch screen such as that illustrated in FIG. 12B, 12F or 12G may be separated from the other touch screens on the substrate.

In block 1030, final processing steps may be performed. The singulated touch screens may, for example, be configured with a touch controller such as touch controller 77, described below with reference to FIG. 14B. Block 1030 may involve combining an individual touch sensor device 900 with a portable device such as device 40, depicted in FIGS. 14A and 14B. Alternatively, block 1030 may involve packaging individual touch sensor devices 900, such as for storage, shipping and/or later assembly.

Additional examples of how the sensor electrodes 907a and 907b may be arranged on a cover glass are provided in FIGS. 12F and 12G. Like FIGS. 12A and 12B, FIGS. 12F and 12G depict a side of the touch sensor device 900 that would face towards a display glass, on the inside of a display device.

FIG. 12F shows an example of a cover glass having first projected capacitive touch sensor electrodes in discontinuous rows and second projected capacitive touch sensor electrodes in continuous columns formed thereon. In this example, the jumpers 1120b electrically connect adjacent sensels of the row sensor electrodes 907a by spanning portions of the continuous columns of the sensor electrodes 907b. The routing wires 1120a provide signals to the row sensor electrodes 907a and the column sensor electrodes 907b.

In some implementations, a touch controller such as touch controller 77 of FIG. 14B may be configured for communication with the routing wires 1120a, e.g., via electrical connections made with the routing wires 1120a in the pad area 1205. The touch controller may be configured to determine changes in capacitance between the sensor electrodes 907. In some implementations, when a finger touches (or is brought near) the touch sensor device 900, the finger may overlap more with a particular sensel 1210 and less with an adjacent sensel 1210. By probing various sensels 1210 in an area of a finger touch, for example, the touch controller may be configured to determine changes in capacitance between the sensels 1210 in the area. In some implementations, the touch controller may be configured to determine a touch centroid according to the combined effect of these changes in capacitance. In some implementations, the touch controller may be configured to represent these changes as a Gaussian envelope to determine a touch location.

FIG. 12G shows an alternative example of a cover glass having first projected capacitive touch sensor electrodes in discontinuous rows and second projected capacitive touch sensor electrodes in continuous columns formed thereon. Like FIG. 12F, FIG. 12G also provides an example in which the sensor electrodes 907a are formed into discontinuous rows and the sensor electrodes 907b are formed into continuous columns. In this example, the jumpers 1120b electrically connect adjacent lines of the row sensor electrodes 907a by spanning loops of the continuous sensor electrodes 907b. The routing wires 1120a provide signals to the row sensor electrodes 907a and the column sensor electrodes 907b.

FIG. 12H shows an example of a top view of a device having projected capacitive touch sensor electrodes and a border area formed of optical cavity layers on a cover glass. FIG. 12H depicts the touch sensor device 900 from a side visible to a viewer even after a display device is assembled. Accordingly, the border area 1105 hides the routing wires 1120a.

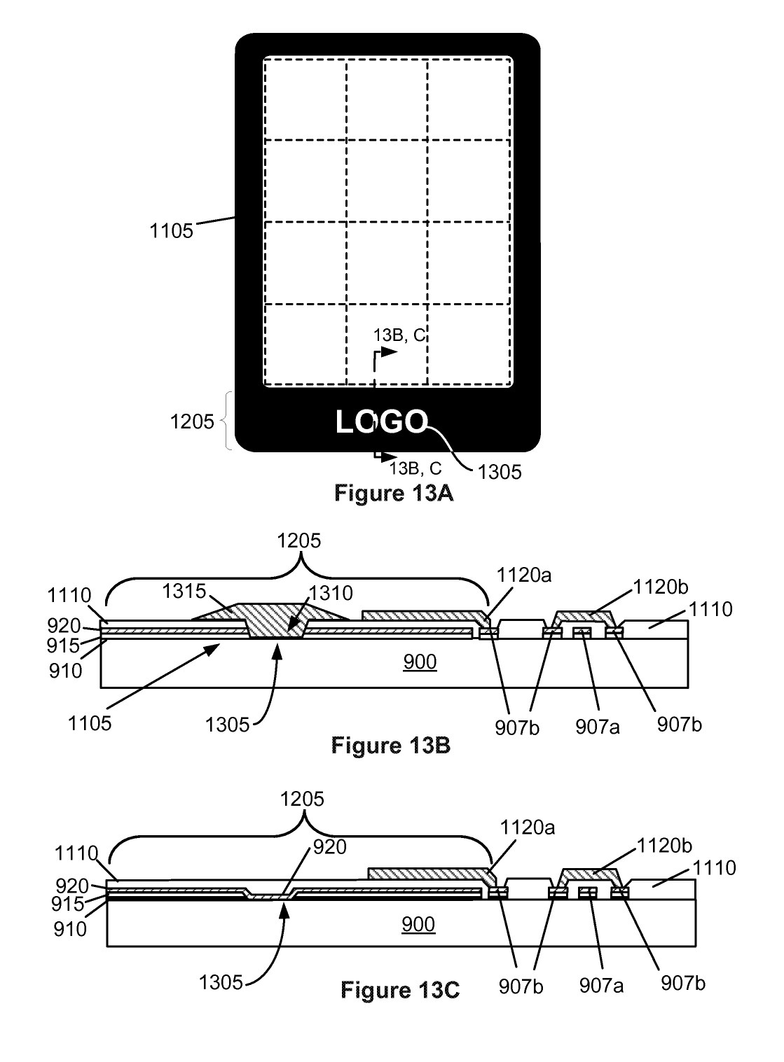

FIG. 13A shows an alternative example of a top view of a device having a border area formed of optical cavity layers on a cover glass, with a logo formed in the border area. In this example, the logo 1305 is formed in the pad area 1205. In alternative implementations, decorative designs, other types of logos, etc., may be formed, whether in the pad area 1205 or in other portions of the border area 1105.

FIG. 13B shows an example of a cross-section through the cover glass, border and logo shown in FIG. 13A. In this example, the logo 1305 has been formed by forming vias 1310 through the substantially transparent dielectric material 1110 and the optical cavity layers 910, 915 and 920 of the border area 1105 to the cover glass 900. The vias 1310 can be made in the shape of a desired logo 1305. Here, the vias 1310 have been filled with ink 1315, which may be white, black or colored. In alternative implementations, the vias 1310 may be filled with other material, such as paint, metal, reflective tape, etc.

FIG. 13C shows an alternative example of a cross-section through the cover glass, border and logo shown in FIG. 13A. In this example, the vias 1310 have been formed through the optical cavity layers 910 and 915 prior to the deposition of the layer 920. Therefore, the reflective surface of the layer 920 is exposed to a viewer in the logo 1305.

In some other implementations, the depth of the optical cavity may be changed in the area of the logo 1305, e.g., by varying the thickness of the substantially transparent oxide layer 915. In this manner, the optical cavity layers 910, 915 and 920 of the border area 1105 may be configured to reinforce a first color (or black) and the optical cavity layers 910, 915 and 920 of the logo 1305 may be configured to reinforce a second color (or black). In one such example, the substantially transparent oxide layer 915 may be formed of SiO₂ and may have a thickness of approximately 165 nm in the logo 1305, configured to reinforce a green color (see FIG. 9C). The substantially transparent oxide layer 915 of the border area 1105 may have a thickness of approximately 72 nm, causing a black appearance (see FIGS. 9B and 9C). The substantially transparent oxide layer 915 of the sensor electrodes 907a and 907b may be made the same thickness as that of the border area 1105 or the logo 1305, or may have another thickness that will reinforce another color.

FIGS. 14A and 14B show examples of system block diagrams illustrating a display device 40 that includes a plurality of interferometric modulators. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna ₄3, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 14B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD (or any other device) as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method, comprising:
depositing optical cavity layers on a substantially transparent substrate to form a plurality of sensor electrodes;
depositing a substantially transparent dielectric material on the optical cavity layers and on exposed areas of the substantially transparent substrate;
forming vias through the substantially transparent dielectric material to expose portions of the underlying optical cavity layers; and
depositing conductive material in the vias to form electrical connections between the portions of the underlying optical cavity layers.

2. The method of claim 1, wherein depositing the optical cavity layers involves depositing black mask layers.

3. The method of claim 2, wherein the black mask layers provide a photopic integrated reflectivity of less than 1% across a wavelength range from 350 nm to 800 nm.

4. The method of claim 1, wherein depositing the optical cavity layers involves depositing at least one of a partially reflective and partially conductive layer, an oxide layer and a reflective and conductive layer.

5. The method of claim 4, wherein depositing the oxide layer involves depositing a silicon dioxide layer or an indium tin oxide layer.

6. The method of claim 4, wherein depositing the partially reflective and partially conductive layer involves depositing a molybdenum-chromium (MoCr) alloy layer.

7. The method of claim 1, wherein the sensor electrodes are formed in a sensing area and wherein depositing the optical cavity layers involves forming a border area that extends around at least part of the sensing area.

8. The method of claim 7, wherein depositing the oxide layer involves forming the optical cavity layers to reinforce a first color in the border area and forming the optical cavity layers of the sensor electrodes to reinforce a second color.

9. The method of claim 7, wherein depositing the conductive material involves forming routing wires and a grounding wire in the border area, further including forming an electrical connection between the grounding wire and a conductive layer of the optical cavity layers in the border area.

10. The method of claim 7, further including forming a via through at least one of the optical cavity layers in the border area to create a decoration.

11. The method of claim 10, wherein the decoration is a logo.

12. The method of claim 7, wherein forming the vias involves forming a via in the border area configured to expose a conductive layer of the optical cavity layers.

13. The method of claim 12, further including connecting the conductive layer to an electrically grounded wire through the via in the border area.

14. The method of claim 1, wherein depositing the optical cavity layers involves forming an optical cavity that will reinforce a wavelength range or color of incident light.

15. The method of claim 1, wherein depositing the conductive material involves forming routing wires in a border area, the routing wires configured for connecting the sensor electrodes with control circuitry.

16. The method of claim 1, wherein depositing the optical cavity layers involves forming projected capacitive touch sensor electrodes.

17. The method of claim 16, wherein depositing the optical cavity layers involves forming first projected capacitive touch sensor electrodes in continuous columns and second projected capacitive touch sensor electrodes in discontinuous rows, and wherein depositing the conductive material involves forming electrical connections between the discontinuous rows.

18. The method of claim 16, wherein depositing the optical cavity layers involves forming first projected capacitive touch sensor electrodes in discontinuous columns and second projected capacitive touch sensor electrodes in continuous rows, and wherein depositing the conductive material involves forming electrical connections between the discontinuous columns.

19. An apparatus, comprising:
a substantially transparent substrate;
a plurality of touch sensor electrodes disposed on the substantially transparent substrate, the touch sensor electrodes including optical cavity layers;
substantially transparent dielectric material disposed on the optical cavity layers;
vias formed through the substantially transparent dielectric material to portions of the optical cavity layers; and
conductive material in the vias to form electrical connections between the portions of the optical cavity layers.

20. The apparatus of claim 19, wherein the optical cavity layers include black mask layers.

21. The apparatus of claim 20, wherein the black mask layers provide a photopic integrated reflectivity of less than 1% across a wavelength range from 350 nm to 800 nm.

22. The apparatus of claim 19, wherein the optical cavity layers include at least one of a partially reflective and partially conductive layer, an oxide layer, and a reflective and conductive layer.

23. The apparatus of claim 22, wherein the optical cavity layers include the oxide layer and wherein the oxide layer includes a silicon dioxide layer or an indium tin oxide layer.

24. The apparatus of claim 22, wherein the optical cavity layers include the partially reflective and partially conductive layer and wherein the partially reflective and partially conductive layer includes a molybdenum-chromium (MoCr) alloy layer.

25. The apparatus of claim 19, further comprising:
a border area around the touch sensor electrodes, wherein the border area is formed of the optical cavity layers.

26. The apparatus of claim 25, wherein first optical cavity layers that form the border area are configured to reinforce a first color and wherein second optical cavity layers that form the touch sensor electrodes are configured to reinforce a second color.

27. The apparatus of claim 19, wherein the optical cavity layers form an optical cavity configured to reinforce a wavelength range or color of incident light.

28. The apparatus of claim 19, wherein the touch sensor electrodes include first touch sensor electrodes in continuous columns and second touch sensor electrodes in discontinuous rows, and wherein the conductive material forms electrical connections between the discontinuous rows.

29. The apparatus of claim 19, wherein the touch sensor electrodes include first touch sensor electrodes in discontinuous columns and second touch sensor electrodes in continuous rows, and wherein the conductive material forms electrical connections between the discontinuous columns.

30. The apparatus of claim 19, further comprising:
a display;
a processor that is configured to communicate with the display, the processor being configured to process image data; and
a memory device that is configured to communicate with the processor.

31. The apparatus of claim 30, further comprising:
a driver circuit configured to send at least one signal to the display; and
a controller configured to send at least a portion of the image data to the driver circuit.

32. The apparatus of claim 30, further comprising:
an image source module configured to send the image data to the processor, wherein the image source module includes at least one of a receiver, transceiver, and transmitter.

33. The apparatus of claim 30, further comprising:
an input device configured to receive input data and to communicate the input data to the processor.

34. The apparatus of claim 30, further comprising:
a touch controller configured for communication with the processor; and
routing wires configured for connecting the sensor electrodes with the touch controller.

35. An apparatus, comprising:
substantially transparent substrate means;
a plurality of touch sensor electrode means disposed on the substantially transparent substrate means, the touch sensor electrode means including optical cavity means; and
electrical connection means for forming electrical connections between discontinuous portions of the touch sensor electrode means.

36. The apparatus of claim 35, wherein the optical cavity means include black mask layers.

37. The apparatus of claim 35, further comprising:
a border area around the touch sensor electrode means, wherein the border area is formed of the optical cavity means.

38. The apparatus of claim 37, further comprising:
touch control means; and
routing means for connecting the touch sensor electrode means with the touch control means, wherein the border area is configured to conceal the routing means.

39. The apparatus of claim 35, wherein the touch sensor electrode means include first touch sensor electrodes in continuous columns and second touch sensor electrodes in discontinuous rows, and wherein the electrical connection means form electrical connections between the discontinuous rows.

40. The apparatus of claim 35, wherein the touch sensor electrode means include first touch sensor electrodes in discontinuous columns and second touch sensor electrodes in continuous rows, and wherein the electrical connection means form electrical connections between the discontinuous columns.
